(19) United States
(12) Patent Application Publication
(10) Pub. No.: US 2019/0118826 A1
(43) Pub. Date: Apr. 25, 2019

(54) VEHICLE CONTROL DEVICE AND OPERATING METHOD THEREFOR

(71) Applicant: Jin Su PARK, Seongnam-si (KR)

(72) Inventor: Jin Su PARK, Seongnam-si (KR)

(21) Appl. No.: 16/092,477

(22) PCT Filed: Dec. 7, 2016
(86) PCT No.: PCT/KR2016/014273

§ 371 Date: Oct. 10, 2018

(30) Foreign Application Priority Data
May 18, 2016 (KR) 10-2016-0061029

(51) Int. Cl. B60W 40/105; E05B 81/72; B60W 50/00; B60W 50/02; G01R 19/00

(52) U.S. Cl. CPC B60W 40/105; E05B 81/72; B60W 50/0098; B60Y 2400/304; G01R 19/0084; B60W 2050/0043; B60W 2540/10; B60W 50/0205

(57) ABSTRACT

Various embodiments of the present invention relate to a vehicle control device and an operating method therefore. According to one embodiment, the vehicle control device includes: an open door determination unit for acquiring an open door measurement value from an on-board diagnostics (OBD) unit of a vehicle; an acceleration sensing unit for acquiring an acceleration value from the OBD unit; and a processing unit for blocking the acquired acceleration value to be transmitted from the OBD unit to an electronic control unit (ECU) and transmitting a default value of the acceleration value to the ECU, when it is determined, on the basis of the open door measurement value, that a vehicle door is open.

### TECHNICAL FIELD

Various exemplary embodiments of the present invention relate to a vehicle control device and an operating method therefore and more particularly, relate to a vehicle control device which controls the driving of a vehicle or acceleration performance of the vehicle when a vehicle door is open and an operating method therefore.

### BACKGROUND ART

In the modern society, vehicles are essential transportation means and many safety accidents are occurring while driving the vehicles. Particularly, safety accidents caused by manipulating an accelerator pedal without checking that the vehicle door is open are greatly increased.

Korean Unexamined Patent Application Publication No. 10-2005-0027422 discloses an auto-lock system of an automobile door and a method for the same which detect a driving time of a vehicle and a driving speed when the vehicle starts driving and automatically lock the door when the driving time of the vehicle is longer than a set time or the driving speed of the vehicle is higher than a predetermined speed.

However, when the door of the vehicle is open, there is a limit to prevent the safety accidents such as falling from the vehicle at the time of departure of the vehicle by manipulating the accelerator pedal or injury due to the open door.

### DISCLOSURE

### Technical Problem

The present invention has been made in an effort to provide a method and a device for preventing safety accidents which may be generated when a vehicle door is open.

According to various exemplary embodiments of the present invention, a vehicle control device which controls the vehicle so as not to be driven when the door is open and an operating method therefore may be provided.

Further, a vehicle control device which controls an acceleration pattern of the vehicle in accordance with a driving mode selected by a user and an operation method therefore may be provided.

### Technical Solution

According to an exemplary embodiment of the present invention, the vehicle control device includes: an open door determination unit which acquires an open door measurement value from an on-board diagnostics (OBD) unit of the vehicle; an acceleration sensing unit which acquires an acceleration value from the OBD unit; and a processing unit which blocks the acquired acceleration value to be transmitted from the OBD unit to an electronic control unit (ECU) and transmits a default value of the acceleration value to the electronic control unit when it is determined that a vehicle door is open based on the open door measurement value.

According to various exemplary embodiments, the open door measurement value may be included as a voltage value corresponding to a vehicle door open state and a vehicle door closed state.

According to various exemplary embodiments, the acceleration value may be included as a voltage value corresponding to a depressed degree of an accelerator pedal of the vehicle.

According to various exemplary embodiments, when it is determined that the vehicle door is closed based on the open door measurement value, the processing unit may transmit the acceleration value acquired from the OBD unit to the electronic control unit.

According to various exemplary embodiments, the vehicle control device may further include: a storage unit in which two or more driving modes are stored and when it is determined that the vehicle door is closed based on the open door measurement value, the processing unit may check selection of the driving mode, reflect a weight value included in the selected driving mode to the acquired acceleration value, and transmit the acceleration value to which the weight value is reflected to the electronic control unit.

According to various exemplary embodiments, the weight value may be included in the storage unit as a voltage value which is added or subtracted to or from the acceleration value or a ratio.

According to various exemplary embodiments, the processing unit may process the acceleration sensing unit to acquire the acceleration value in accordance with a time interval included in the selected driving mode.

According to various exemplary embodiments, the vehicle control device may further include an attachable connecting unit which is connected to the open door determination unit and the acceleration sensing unit and the connecting unit may be connected to an input/output terminal configured in at least one of the OBD unit and the electronic control unit.

According to various exemplary embodiments, the processing unit may transmit a notification message for at least one of a vehicle door open state, a driving mode of the vehicle, and fuel efficiency to at least one external device to output the notification message.

### Advantageous Effects

According to various exemplary embodiments of the present invention, it is possible to check the door closed state and control the vehicle to be driven so that safety accidents which may occur when the vehicle is driven in the vehicle door open state may be prevented.

According to various exemplary embodiments of the present disclosure, various driving modes which can be selected in the vehicle are provided so that it is possible to effectively respond to various demands of users on a driving environment of the vehicle.

### DESCRIPTION OF THE DRAWINGS

FIG. 1 illustrates a vehicle control device according to an exemplary embodiment of the present invention and a vehicle control system including a vehicle control device.

FIG. 2 is a flowchart of an operation of controlling departure of a vehicle based on a door open state in a vehicle control device according to an exemplary embodiment of the present invention.

FIG. 3 is a flowchart of an operation of controlling an acceleration value in accordance with a driving mode in a vehicle control device according to an exemplary embodiment of the present invention.

FIG. 4 is a flowchart of an operation of controlling an acceleration value in accordance with a state of a transmission in a vehicle control device according to an exemplary embodiment of the present invention.

FIG. 5 is a view of a vehicle mounted with a vehicle control device according to an exemplary embodiment of the present invention and a view illustrating a voltage graph in accordance with a door open state and manipulation of an accelerator pedal.

FIG. 6 is a view illustrating a vehicle control device according to an exemplary embodiment of the present invention and an external device which is connected to the vehicle control device through network communication.

### BEST MODE FOR INVENTION

According to another exemplary embodiment of the present invention, an operating method of a vehicle control device includes: acquiring an open door measurement value from an on-board diagnostics (OBD) unit of the vehicle; blocking an acceleration value which is transmitted from an OBD unit to an electronic control unit (ECU) when it is determined that a vehicle door is open based on the open door measurement value; and transmitting a default value of the acceleration value to the electronic control unit.

### MODE FOR INVENTION

Hereinafter, exemplary embodiments of the present disclosure will be described in detail with reference to the accompanying drawings so as for those skilled in the art to easily carry out the present disclosure.

In various exemplary embodiments of the present invention, it should be understood that, when it is described that an element is “coupled” or “connected” to another element, the element may be “directly coupled” or “directly connected” to another element or “coupled” or “connected” to another element through a third element.

It is obvious that a device (hereinafter, referred to as a vehicle control device) according to various exemplary embodiments of the present invention is replaced by the same or similar device unless explicitly stated otherwise. Further, the vehicle control device according to various exemplary embodiments of the present invention may be configured by a combination of one or more of various devices described herein. For example, the device may be provided as at least some of the described devices or a structure including at least some of the functions of the device.

Hereinafter, the vehicle control device according to various exemplary embodiments will be described with reference to the accompanying drawings. In various exemplary embodiments, when a term “user” or “driver” is described, it may refer a person or a device (for example, an artificial intelligent vehicle control device) that uses the vehicle control device.

An electronic control unit (ECU) of a vehicle controls an operation of the vehicle based on various statuses acquired through an on-board diagnostics (OBD) unit. For example, the electronic control unit adjusts a fuel injection amount of an engine in accordance with a movement (or manipulation) of an accelerator pedal which is checked through the OBD unit to control the acceleration of the vehicle.

Here, the OBD unit of the vehicle may include at least some of Korean On-Board Diagnosis (KOBD), On-Board Diagnosis Version I (OBD-1), OBD-2, and European On-Board Diagnosis (EOBD).

According to various exemplary embodiments of the present invention, a vehicle control device which checks movement information of the accelerator pedal of the vehicle and door open state information of the vehicle from the OBD unit of the vehicle, controls (for example, changes or maintains) acceleration measurement information of the accelerator pedal in accordance with the door open state information of the vehicle and transmits the controlled acceleration measurement information to the electronic control unit and an operating method thereof may be provided.

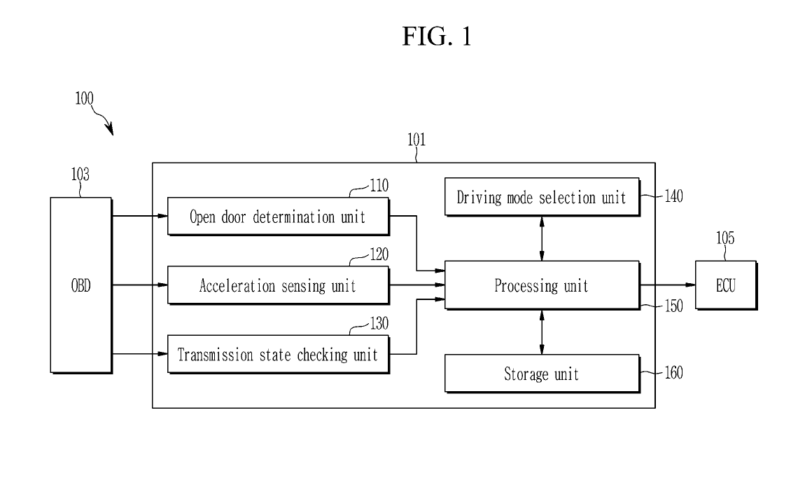

Hereinafter, an operation of the vehicle control device will be described in detail with reference to FIGS. 1 to 6.

FIG. 1 illustrates a vehicle control device 101 according to an exemplary embodiment of the present invention and a vehicle control system including the vehicle control device 101. The vehicle control system 100 includes the vehicle control device 101 and further includes at least one of an OBD unit 103 and an electronic control unit 105 which are equipped in the vehicle. Here, the vehicle control device 101, the OBD unit 103, and the electronic control unit 105 may be connected to each other through controller area network (CAN) communication.

The vehicle control device 101 includes at least one constituent element of an open door determination unit 110, an acceleration sensing unit 120, a transmission state checking unit 130, a driving mode selection unit 140, a processing unit 150, and a storage unit 160. Here, each constituent element may be represented by a module which is distinguished according to an operation and a function and in this case, the module may be configured by a software module or a hardware module.

The open door determination unit 110 may acquire door open state information of the vehicle from the OBD unit 103 included in the vehicle. For example, the open door determination unit 110 checks a door open (opened door) state output signal of the OBD unit 103 to acquire the door open state information of the vehicle.

Here, the door open state information acquired from the OBD unit 103 may be acquired (or extracted) by a voltage value (hereinafter, referred to as an open door measurement value) of 0 V to 5 V. Here, the open door determination unit 110 may acquire a predetermined open door measurement value in accordance with an open state or a closed state of the vehicle door.

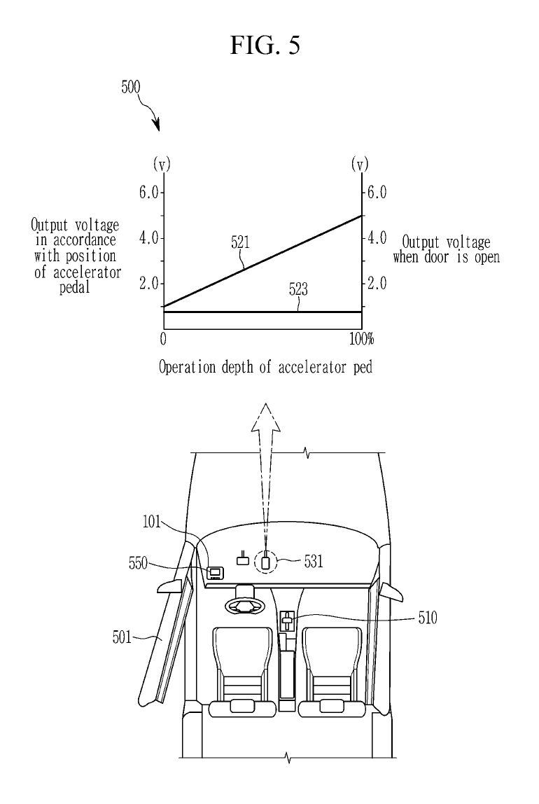

For example, as illustrated in FIG. 5, when at least one door 501 among doors configured in the vehicle is open, the open door determination unit 110 may acquire an open door measurement value of 0 V to 1 V, desirably, 0.7 V from the OBD unit 103. Further, when all doors configured in the vehicle are closed, the open door determination unit 110 may acquire an open door measurement value of 4 V to 5 V, desirably, 4.3 V, from the OBD unit 103. The open door determination unit 110 may transmit the acquired open door measurement value to the processing unit 150.

The acceleration sensing unit 120 may acquire acceleration measurement information corresponding to movement information (for example, a depressed degree) of the accelerator pedal (accelerator) included in the vehicle from the OBD unit 103. For example, the acceleration sensing unit 120 may acquire the acceleration measurement information of the vehicle by checking the accelerator pedal output signal of the OBD unit 103.

Here, the acceleration measurement information (an acceleration measurement value and hereinafter, referred to as an acceleration value) acquired from the OBD unit 103 may be measured by a voltage value within a predetermined range, for example, a voltage value of 0 V to 5 V. In this case, the acceleration sensing unit 120 may acquire an acceleration value from the OBD unit 103 via an analog-to-digital converter (ADC). The acceleration value is transmitted to the electronic control unit 105 of the vehicle to be processed to control acceleration of the vehicle in accordance with a voltage value of the vehicle measurement value.

For example, when the accelerator pedal is not depressed, the acceleration sensing unit 120 may acquire an acceleration value of 0 V to 1 V, desirably, 0.7 V, from the OBD unit 103. Further, the acceleration sensing unit 120 may acquire the acceleration value which is increased in accordance with a movement degree of the accelerator pedal (for example, a depressed degree).

The acceleration sensing unit 120 may transmit the acquired acceleration value to the processing unit 150. Here, the acquired acceleration value may be checked as a designated value (for example, voltage (V)) in accordance with the position of the accelerator pedal and checked as a variation (V/sec) in accordance with the change of the accelerator pedal.

The transmission state checking unit 130 checks a state of a transmission of the vehicle through a transmission measurement value acquired from the OBD unit 103. For example, the transmission state checking unit 130 may check a state of a driving gear, a neutral gear, a parking gear, and/or a reverse gear of the vehicle.

The driving mode selection unit 140 selects at least one driving mode stored in the storage unit 160 and calls data of the selected driving mode by means of an input unit. In this case, the driving mode stored in the storage unit 160 may include a weight value for controlling an acceleration value for the selected driving mode.

The processing unit 150 controls the acceleration value transmitted to the electronic control unit 105 based on the open door measurement value received from the open door determination unit 110. For example, when the processing unit 150 checks that the door open state value received from the open door determination unit 110 is 0.7 V, the processing unit 150 may determine that the vehicle door is open. In this case, the processing unit 150 may transmit a setting value stored in the storage unit to the electronic control unit 105. In this case, the processing unit 150 may transmit an acceleration value to the electronic control unit 105 through a DAC (digital-to-analog converter).

According to various exemplary embodiments of the present invention, when the processing unit 150 checks that the vehicle door is open, the processing unit 150 may control the accelerator pedal of the vehicle so as not to operate. Clearly, instead of the acceleration value corresponding to the movement of the accelerator pedal of the vehicle, the processing unit may transmit a default value (or a set value stored in the storage unit 160) at which the accelerator pedal does not move (or is not depressed) to the electronic control unit 105 as an acceleration value. Here, as illustrated in a graph 500 of FIG. 5, the acceleration value (or a default value or a cut-off value of the acceleration value) which is transmitted to the electronic control unit 105 in a state when the door of the vehicle is open may be set to maintain (523) a cut-off value of 0 V to 1 V, desirably 0.7 V which is acquired from the OBD unit 103 in a state when the accelerator pedal 531 is not depressed (or an idle state). Alternatively, the cut-off value which is transmitted to the electronic control unit 105 in a vehicle door open state may be defined as a voltage value for maintaining an RPM (or for injecting fuel to the engine) such that the engine does not stop due to the reduction of an engine output or the engine maintains a starting status without stopping.

In contrast, when the processing unit 150 checks that the door open state value received from the open door determination unit 110 is 4.3 V, the processing unit 150 may determine that all the vehicle doors are closed. In this case, as illustrated in the graph 500 of FIG. 5, the processing unit 150 may transmit the acceleration value 521 which is received from acceleration sensing unit 120 in accordance with a depressed state of the accelerator pedal 531 to the electronic control unit 105.

In addition, the processing unit 150 may control the acceleration measurement value to be transmitted to the electronic control unit 105 in accordance with a selected driving mode. For example, the driving mode selection unit 140 may select a driving mode such as a sports mode, a normal mode, and an ECO mode (or a fuel efficiency mode, ECO) in accordance with a user input. Here, the processing unit 150 may increase or decrease the acceleration value using a weight value set for the driving mode selected by the driving mode selection unit 140.

According to various exemplary embodiments, the electronic control unit 105 receives the acceleration value transmitted from the OBD unit 103 through an acceleration value input unit of the electronic control unit 105 and determines to depart and/or accelerate the vehicle based on the received acceleration value.

Here, when the processing unit 150 checks that the vehicle control device 101 is connected to the OBD unit 103 and the electronic control unit 105, the processing unit 150 blocks the acceleration value transmitted from the acceleration value output unit of the OBD unit 103 from being transmitted to an acceleration value input unit of the electronic control unit 105 and for example, selectively transmits the acceleration value to the acceleration value input unit of the electronic control unit 105 based on the open door measurement value, as described above, in accordance with a predetermined condition.

In contrast, referring to FIG. 1, although it is described that the vehicle control device 101 selectively transmits the acceleration value received from the OBD unit 103 to the electronic control unit 105, the processing unit 150 may not block the acceleration value transmitted from the acceleration value output unit of the OBD unit 103 from being transmitted to the acceleration value input unit of the electronic control unit 105.

Accordingly, the processing unit 150 may change output data of the acceleration value output unit of the OBD unit 103 or acceleration value output data of the OBD unit 103 so as to output an acceleration value output based on the open door measurement value through the acceleration value output unit of the OBD unit 103. In this case, the electronic control unit 105 may receive the acceleration value output through the vehicle control device 101 through the acceleration value output unit of the OBD unit 103.

The storage unit 160 stores information processed in at least one of the open door determination unit 110, the acceleration sensing unit 120 and the processing unit 150. Further, the storage unit 160 may store set values for various driving modes.

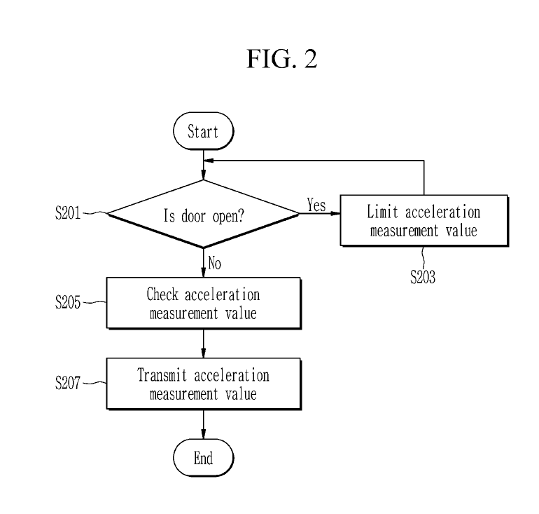

Referring to FIG. 2, the processing unit 150 determines whether the door of the vehicle is open through an open door measurement value acquired from the OBD unit 103 in step S201. For example, when the open door measurement value checked through the open door determination unit 110 is 0.7 V, the processing unit 150 may determine that at least one vehicle door is open.

In this case, the processing unit 150 controls the acceleration value transmitted from the acceleration sensing unit 120 to the electronic control unit 105 in step S203. For example, the acceleration value checked from the acceleration sensing unit 120 is not transmitted to the electronic control unit 105 but a predetermined cut-off value (for example, 0.7 V) corresponding to the open door measurement value 0.7 V may be transmitted to the electronic control unit 105.

Here, the predetermined cut-off value (for example, 0.7 V) corresponding to the open door measurement value 0.7 V may be a voltage value which is measured in a state when the accelerator pedal is not moved by the user (for example, a default or idle state).

In contrast, when the open door measurement value checked from the open door determination unit 110 is 4.3V, the processing unit 150 may determine that all the vehicle doors are closed. In this case, the processing unit 150 acquires an acceleration value through the acceleration sensing unit 120 in step S205 and transmits the acquired acceleration value to the electronic control unit in step S207.

According to various exemplary embodiments, the vehicle control device 101 may check whether there is an error while determining the door open state of the vehicle by the open door determination unit 110. For example, when the processing unit 150 checks that a door open state or a door closed state is repeatedly generated (for example, five times or ten times or more) for a predetermined time (for example, one second) designated based on the door open state value received from the open door determination unit 110, the processing unit 150 may determine that an error is incurred in the door open state value for the corresponding door.

In this case, the processing unit 150 may determine and process that the door open state value is a value for a door open state or a door closed state in accordance with the predetermined value stored in the storage unit 160 or determine that an open door sensing sensor erroneously operates by the error of the door open state value.

For example, when it is determined that an error is incurred in at least one door open state by the open door determination unit 110, the door open state value may be set to determine that the door is open. In this case, as described above, when it is determined that an error is incurred in the door open state, the processing unit 150 may determine that the door is open and correspondingly transmit a cut-off value to the electronic control unit 105.

In contrast, when it is determined that an error is incurred in at least one door open state by the open door determination unit 110, the door open state value may be set to determine that the door is closed. In this case, as described above, when it is determined that an error is incurred in the door open state, the processing unit 150 may determine that the door is closed and transmit a correspondingly measured acceleration value to the electronic control unit 105. In this case, the processing unit 150 may apply a predetermined weight value to the acceleration measurement value in accordance with the driving mode and/or a transmission state.

In the meantime, as another exemplary embodiment, when it is determined that an error is incurred in the door open state, it may be determined that the open door sensing sensor which measures a door open state erroneously operates and when it is determined that the open door sensing sensor erroneously operates, an erroneous operation of the open door sensing sensor is notified to a driver and a signal of the open door sensing sensor may be blocked.

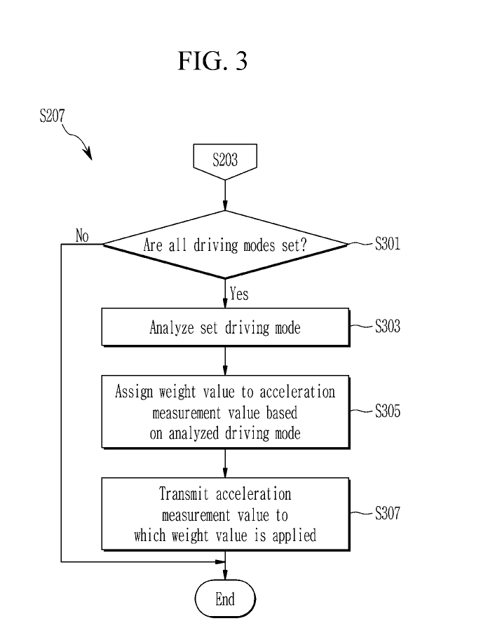

According to various exemplary embodiments, the vehicle control device 101 may additionally perform an operation of applying a weight value corresponding to the selected driving mode to an acceleration value and transmitting the weight value to the electronic control unit 105 (see FIG. 3). Here, the exemplary embodiment of FIG. 3 may be operations which are additionally performed in an operation S207 of transmitting an acceleration value of FIG. 2 to the electronic control unit 105.

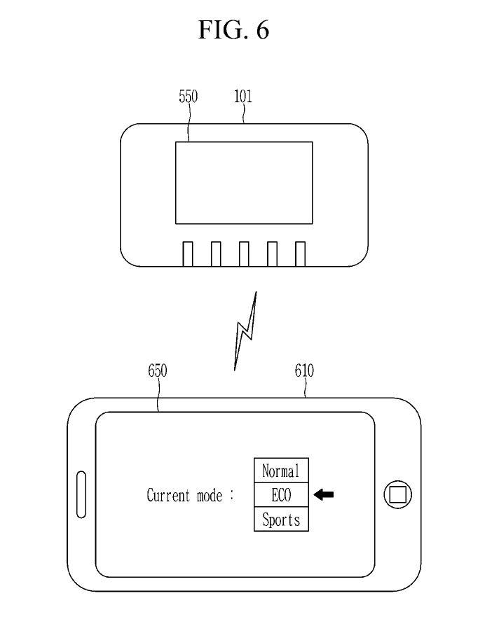

Referring to FIGS. 5 and 6, the vehicle control device 101 may include at least one output unit(or a display unit) 550. In this case, the processing unit 150 may display various driving modes stored in the storage unit 160 by means of the output unit 550. The driving mode selection unit 140 may select at least one driving mode through a user input.

Here, the driving mode includes a sports mode, a normal mode, and an ECO mode and each driving mode may include a weight value of the acceleration value. For example, the normal mode may be a mode in which an acceleration value is not corrected.

The sports mode may be a mode for using an engine output relatively high in the same operation of the accelerator pedal as compared with the normal mode. For example, the sports mode may include positive (+, plus) weight value information of a value designated to be applied to the acceleration value.

The ECO mode may be a mode for relatively improving fuel efficiency in the same operation of the accelerator pedal as compared with the normal mode. For example, the ECO mode may include negative (−, minus) weight value information of a value designated to be applied to the acceleration value.

The driving mode selection unit 140 calls a predetermined weight value in accordance with the selected driving mode and transmits the predetermined weight value to the processing unit 150. Here, the weight value may be provided as a voltage value which is the same unit as the acceleration value or provided as a ratio (for example, percent, %). Here, when the weight value is provided as a voltage value, the processing unit 150 may add or subtract the weight value to or from the acceleration value to determine an acceleration value (for example, a corrected acceleration value) to which the weight value is applied.

In addition, at least some (for example, the sports mode and the ECO mode) of the driving modes are not limited to include weight value information to be applied to the acceleration measurement value and may further include a transmission time range of the acceleration value.

For example, the sports mode is not only a mode for using an engine output high, but also a mode for quickly reflecting a movement state change of the accelerator pedal. According to an exemplary embodiment, the sports mode may be set to transmit an acceleration value to the electronic control unit 105 at a shorter time interval than the normal mode.

In contrast, the ECO mode is a mode for smoothly maintaining an engine reaction in accordance with the movement state change of the accelerator pedal to improve fuel efficiency. According to an exemplary embodiment, the ECO mode may be set to transmit an acceleration value to the electronic control unit 105 at a longer time interval than the normal mode.

In addition, when the acceleration value received from the acceleration sensing unit 120 is increased, the ECO mode may be set to transmit the acceleration value to the electronic control unit 105 at a longer time interval than the normal mode and when the acceleration value received from the acceleration sensing unit 120 is decreased, the ECO mode may be set to transmit the acceleration value to the electronic control unit 105 at a shorter time interval than the normal mode.

As described above, when the driving mode further includes a transmission time range for correcting the acceleration value, the processing unit 150 may determine an acceleration value to be transmitted to the electronic control unit 105 in consideration of the weight value and/or the transmission time range.

According to various exemplary embodiments, as illustrated in FIG. 6, the vehicle control device 101 may be connected to at least one external device 610. In this case, the vehicle control device 101 may output information on the driving of the vehicle through a connected external device 610 (for example, an output unit 650 of the connected external device).

For example, the processing unit 150 may generate output data to display information on a driving mode, a driving type (or a driving habit) and a fuel efficiency selected during a predetermined period (for example, daily, weekly, or monthly) during the driving of the vehicle to transmit the output data to the external device. In this case, the external device which receives the output data from the vehicle control device 101 may output information included in the received output data, for example, information on a driving mode, a driving type and/or fuel efficiency.

According to various exemplary embodiments, the vehicle control device 101 may receive the driving mode and change information on a setting value set for each driving mode from the external device and modify the setting value in accordance with the received change information.

Referring to FIG. 3 again, the processing unit 150 checks whether the driving mode is selected by means of the driving mode selection unit 140 in step S301. In this case, when the selected driving mode is checked, the driving mode selection unit 140 analyzes the checked driving mode in step S303.

For example, the processing unit 150 may check the weight value of the acceleration value and/or the transmission time range of the acceleration value corresponding to the selected driving mode. Here, the weight value of the acceleration value and/or the transmission time range of the acceleration value may be called through the driving mode selection unit 140 in the form of a matching table.

According to an exemplary embodiment, when the driving mode of the vehicle control device 101 is selected as a normal mode by the driving mode selection unit 140, the processing unit 150 may determine to transmit the acceleration value acquired from the acceleration sensing unit 120 to the electronic control unit 105 without being corrected.

Further, when the driving mode of the vehicle control device 101 is selected as a sports mode by the driving mode selection unit 140, the processing unit 150 may set to apply the positive (+, plus) weight value designated for the sports mode to the acceleration value acquired from the acceleration sensing unit 120 and set a time interval for acquiring the acceleration value from the OBD unit 103.

Further, when the driving mode of the vehicle control device 101 is selected as an ECO mode by the driving mode selection unit 140, the processing unit 150 may set to apply the negative (−, minus) weight value designated for the ECO mode to the acceleration value acquired from the acceleration sensing unit 120 and set a time interval for acquiring the acceleration value from the OBD unit 103.

The processing unit 150 applies a designated weight value to the acceleration value checked by the acceleration sensing unit 120 in step S305 and transmits the weight value applied acceleration value to the electronic control unit 105 via the processing unit 150 in step S307.

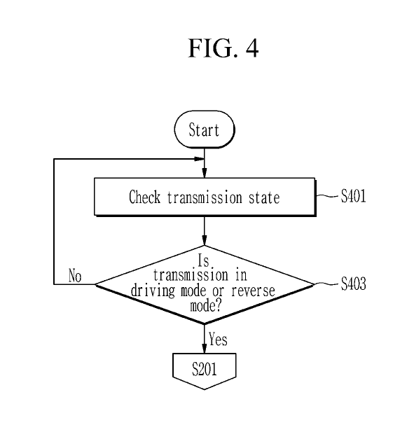

In addition, according to various exemplary embodiments, the vehicle control system 100 may obtain a state of a transmission 510 (a transmission of FIG. 5) through the OBD unit 103. In this case, the vehicle control device 101 may additionally perform an operation of controlling the acceleration value in consideration of not only the open door measurement value of the vehicle, but also a state of the transmission received from the transmission state checking unit 130 (hereinafter, referred to as a transmission measurement value) (see FIG. 4).

Here, even though it is illustrated that the exemplary embodiment of FIG. 4 is processed before performing an operation S201 of checking a door open state, the exemplary embodiment is not limited thereto and may be performed after determining that all the vehicle doors are closed by checking the door open state in step S201.

Referring to FIG. 4, the processing unit 150 checks the transmission measurement value of the vehicle by means of the transmission state checking unit 130 in step S401. Here, the transmission measurement value of the vehicle may allow to check a state of at least one of a driving gear, a neutral gear, a parking gear, and/or a reverse gear by a voltage value of a designated range.

When the checked transmission measurement value is a neutral gear or a parking gear, the processing unit 150 controls the acceleration value transmitted from the acceleration sensing unit 120 to the electronic control unit 105 in step S203. For example, the checked acceleration value checked from the acceleration sensing unit 120 is not transmitted to the electronic control unit 105, but a predetermined cut-off value (for example, 0.7 V) corresponding to the open door measurement value 0.7 V may be transmitted to the electronic control unit 105.

In this case, the processing unit 150 may output a notification message for the door open state of the vehicle. For example, when the vehicle control device 101 includes a speaker, the processing unit 150 may output the notification message for the door open state as an audio message. Alternatively, as illustrated in FIG. 5, when the vehicle control device 101 includes an output unit 550, the notification message for the door open state may be displayed by a graphic interface.

In contrast, when the checked transmission measurement value is one of the driving gears, the processing unit 150 may perform the operation S201 of checking a door open state of FIG. 2.

As described above, according to various exemplary embodiments of the present invention, the vehicle control device 101 checks the door closed state and controls the vehicle to be driven so that safety accidents which may occur when the vehicle is driven in the vehicle door open state may be prevented.

Here, the vehicle control device 101 according to various exemplary embodiments of the present invention may be provided as an independent module which is connected at least some of an input/output terminal of the OBD unit of the vehicle and an input/output terminal of the electronic control unit.

For example, the vehicle control device 101 may include at least one connecting unit (or connector). In this case, at least one of the open door determination unit 110, the acceleration sensing unit 120, and the transmission state checking unit 130 may be connected to the input/output terminal of the OBD unit 103 and/or the electronic control unit 105 via the connecting unit.

Further, the vehicle control device 101 is not limited to control the acceleration value to be transmitted to the electronic control unit 105 in accordance with the door open state, the transmission state and/or the driving mode as described above. Further, as described above, the processing unit 150 transmits a cut-off value based on the door open state, the transmission state, the vehicle error and/or driving mode of the vehicle checked from the vehicle control device 101 to the electronic control unit 105, in addition to various vehicle equipment errors, or transmits a measured acceleration value and/or a weight value applied acceleration value to the electronic control unit 105. However, it is not limited thereto and the processing unit may transmit various setting values to the electronic control unit 105.

For example, when the vehicle control device 101 detects an error of the door open state and/or a vehicle equipment error, the vehicle control device 101 does not transmit the cut-off value for controlling the idle state of the engine to be maintained to the electronic control unit 105 but transmits a stable value (for example, 1 V) to the electronic control unit 105 to maintain a designated speed (or an acceleration).

Further, the vehicle control device 101 may transmit the cut-off value or the stable value to the electronic control unit 105 based on the door open state, the transmission state and/or an operation of a brake pedal without considering the operation of the accelerator pedal.

For example, when at least one of a state when at least one door is open, a state when a brake pedal is manipulated, and a neutral gear state or a parking gear state of the transmission is checked, the cut-off value may be transmitted to the electronic control unit 105.

In contrast, when at least one of a state when at least one door is closed, a state when a brake pedal is not manipulated, and a driving gear state of the transmission is checked, the stable value may be transmitted to the electronic control unit 105.

According to various exemplary embodiments, the operation of transmitting the stable value to the electronic control unit 105 by the vehicle control device 101 may be set to be processed in a state when a mode of the vehicle is selected to be a specific mode (for example, an inspection mode).

According to an exemplary embodiment, when an accelerator operates in a state when the operation of the vehicle control device 101 is an inspection mode, if an output of the acceleration value is changed to be more than a predetermined variation, for example, if the acceleration value is 1 V/sec or higher, the vehicle control device 101 may controls the acceleration value transmitted to the electronic control unit 105 to be 1 V.

As described above, the vehicle control device 101 is mounted in a vehicle which does not provide various driving modes or provided to use various driving modes in the vehicle so that it is possible to effectively respond to various demands of users on a driving environment of the vehicle.

According to various exemplary embodiment, at least some of the device and the method according to various exemplary embodiments disclosed in claims and/or specification of the present invention may be implemented by hardware, software, firmware, or a configuration (for example, a module or unit) including a combination of two or more of hardware, software and firmware. The module may be the minimum unit or a part of an integrally configured component and may be a minimum unit or a part thereof which performs various exemplary embodiments of the present invention. The module may be mechanically or electronically implemented. When the module is implemented by software, a computer readable storage medium which stores at least one program (or a programming module and application) may be provided. For example, software may be implemented as instructions stored in a computer readable storage medium in the form of a programming module. At least one program may be provided to include instructions which allow the vehicle control device to execute methods according to the exemplary embodiments described in the claims and/or specification of the present invention. When the instructions are executed by at least one controller (for example, processing unit 150), the at least one processor may perform the function corresponding to the instruction. The computer readable storage medium may be the storage unit 160. For example, at least a part of the programming module may be implemented (for example, executed) by the controller. At least a part of the programming module may include a module, a program, a routine, sets of instructions for performing at least one function.

The computer readable recording media may include magnetic media such as a hard disk, a floppy disk, and a magnetic tape, optical media such as CD-ROM (Compact Disc Read Only Memory) or DVD (Digital Versatile Disc), magneto-optical media such as a floptical disk, a hardware device which stores and performs a program command (for example, programming module) such as ROM (Read Only Memory), RAM (Random Access Memory), and a flash memory, an electrically erasable programmable read only memory (EEPROM), a magnetic disc storage device or another type of optical storage device and magnetic cassette. Alternatively, the module may be stored in a memory configured by a combination of some or all the above-mentioned recording media. Further, a plurality of constituent memories may be included.

In addition, the module may be stored in an attachable storage device which is accessible to the vehicle control device through a communication network such as Internet, Intranet, LAN (Local Area Network), WLAN (Wide LAN), CAN (Controller Area Network) or SAN (Storage Area Network) or a communication network configured by a combination thereof. The storage device may access the vehicle control device through an external port. Further, a separate storage device on the communication network may access a portable vehicle control device. The above-described hardware device may be configured to operate as at least one software module to perform an operation according to various exemplary embodiments of the present invention and vice versa.

The module or the programming module according to various exemplary embodiments of the present invention may include at least one or more of the above-described constituent elements or omit some of them or further include additional other constituent elements. Operations which are performed by the module or the programming module according to various exemplary embodiments of the present invention or other constituent elements may be executed by sequential, parallel, repetitive, or heuristic method. Further, some operation may be performed in a different order or omitted or another operation may be added thereto.

The exemplary embodiments of the present invention disclosed in the specification and the drawings suggest specific examples for easy description of technical contents of the present invention and easy understanding of the present invention, but do not limit the scope of the present invention. Therefore, it should be understood that all modifications or variations deducted based on the technical spirit of the present invention are included in the scope of the present invention in addition to the exemplary embodiments disclosed herein.

### INDUSTRIAL APPLICABILITY

The present invention provides a vehicle control system so that it has industrial applicability.

1. A vehicle control device, comprising:
an open door determination unit which acquires an open door measurement value from an on-board diagnostics (OBD) unit;
an acceleration sensing unit which acquires an acceleration value from the OBD unit; and
a processing unit which blocks the acquired acceleration value to be transmitted from the OBD unit to an electronic control unit (ECU) and transmits a default value of the acceleration value to the electronic control unit when it is determined that a vehicle door is open based on the open door measurement value.

2. The vehicle control device of claim 1, wherein the open door measurement value is included as a voltage value corresponding to a vehicle door open state and a vehicle door closed state.

3. The vehicle control device of claim 1, wherein the acceleration value is included as a voltage value corresponding to a depressed degree of an accelerator pedal of the vehicle.

4. The vehicle control device of claim 1, wherein when it is determined that the vehicle door is closed based on the open door measurement value, the processing unit transmits the acceleration value acquired from the OBD unit to the electronic control unit.

5. The vehicle control device of claim 4, further comprising:
a storage unit in which two or more driving modes are stored,
wherein when it is determined that the vehicle door is closed based on the open door measurement value, the processing unit checks selection of the driving mode, reflects a weight value included in the selected driving mode to the acquired acceleration value, and transmits the acceleration value to which the weight value is reflected to the electronic control unit.

6. The vehicle control device of claim 5, wherein the weight value is included in the storage unit as a voltage value which is added or subtracted to or from the acceleration value or a ratio.

7. The vehicle control device of claim 5, wherein the processing unit processes the acceleration sensing unit to acquire the acceleration value in accordance with a time interval included in the selected driving mode.

8. The vehicle control device of claim 1, further comprising:
an attachable connecting unit which is connected to the open door determination unit and the acceleration sensing unit,
wherein the connecting unit is connected to an input/output terminal configured in at least one of the OBD unit and the electronic control unit.

9. The vehicle control device of claim 1, wherein the processing unit transmits a notification message for at least one of a vehicle door open state, a driving mode of the vehicle, and fuel efficiency to at least one external device to output the notification message.

10. An operating method of a vehicle control device, comprising:
acquiring an open door measurement value from an on-board diagnostics (OBD) unit;
blocking an acceleration value which is transmitted from an OBD unit to an electronic control unit (ECU) when it is determined that a vehicle door is open based on the open door measurement value; and
transmitting a default value of the acceleration value to the electronic control unit.

11. The operating method of claim 10, wherein the open door measurement value is included as a voltage value corresponding to a vehicle door open state and a vehicle door closed state.

12. The operating method of claim 10, wherein the acceleration value is included as a voltage value corresponding to a depressed degree of an accelerator pedal of the vehicle.

13. The operating method of claim 10, further comprising:
transmitting the acceleration value acquired from the OBD unit to the electronic control unit when it is determined that the vehicle door is closed based on the open door measurement value.

14. The operating method of claim 13, further comprising:
checking selection of the driving mode when it is determined that the vehicle door is closed based on the open door measurement value;
reflecting a weight value included in the selected driving mode to the acquired acceleration value; and
transmitting the acceleration value to which the weight value is reflected to the electronic control unit.

15. The operating method of claim 13, wherein the weight value is included in the storage unit as a voltage value which is added or subtracted to or from the acceleration value or a ratio.

16. The operating method of claim 13, further comprising:
processing the acceleration sensing unit to acquire the acceleration value in accordance with a time interval included in the selected driving mode.

17. The operating method of claim 10, further comprising:
checking connection with an input/output terminal configured in at least one of the OBD unit and the electronic control unit through an attachable connecting unit.

18. The operating method of claim 10, further comprising:
transmitting a notification message indicating at least one of a vehicle door open state, a driving mode of the vehicle, and fuel efficiency to at least one external device to output the notification message.
